(19) United States
(12) Patent Application Publication
(10) Pub. No.: US 2005/0289435 A1
(43) Pub. Date: Dec. 29, 2005

(54) Fast approximate DINV calculation in parallel with coupled ECC generation or correction

(76) Inventors: Dean A. Mulla, Saratoga, CA (US); Dan L. Tu, Santa Clara, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/880,626

(22) Filed: Jun. 29, 2004

(51) Int. Cl. G06F 13/00; G06K 5/04; H03M 13/00

(52) U.S. Cl. 714/758

(57) ABSTRACT

A method, apparatus, and system are disclosed. In one embodiment the method comprises determining whether to invert a first group of data bit signals and performing error checking and correction on the first group of data bit signals in parallel with the inversion determination.

### FIELD OF THE INVENTION

The invention relates to data bus inversion and error correcting code. More specifically, the invention relates to performing data bus inversion calculations and error correcting code calculations in parallel to reduce, and potentially minimize the latency required if both calculations were done in series.

### BACKGROUND OF THE INVENTION

Data bus inversion (DBI) is an important aspect of bus power management and electrical reliability. DBI can aid bus power management by guaranteeing that no more than 50% of the lines of a given bus need to be driven high at any time. The term “driven high” denotes a high voltage as opposed to a low voltage, or a logical one as opposed to a logical zero. DBI also helps with electrical switching because if it can be guaranteed that fewer bus lines switch in a given cycle, there will be less chance of electrical problems related to the switching. A bus that employs a data bus inversion technique will have, for example, a processor sending data out onto a bus. The bus includes numerous data signal lines that each transmits one bit of data at a time. If the bus is 64-bits wide any binary number can be represented on the bus from 0 to 2⁶⁴−1. Certain numbers in that range consist of many more logical ones than logical zeroes. In these instances a bus employing data bus inversion will invert every data signal line and mark the data as “inverted.” Thus, every logical one becomes a logical zero, and every logical zero becomes a logical one. If, for instance, the represented number on the bus has 48 logical ones and 16 logical zeroes, the bus would have to have three quarters of the data signal lines driven high for that particular data cycle without data bus inversion. Although, with data bus inversion employed, only 16, or one quarter, of the lines end up being high (a logical one) and three quarters can remain low (a logical zero).

Another area of importance in computer systems is error correcting code (ECC) generation and correction. Implementing ECC on data transmissions over a bus entails that each data signal conform to specific rules of construction. Thus, departures from this construction in the received signal can generally be automatically detected and corrected. ECC maintains data integrity on data communication buses that would otherwise potentially create faults during data transmission.

### BRIEF DESCRIPTION OF THE DRAWINGS

The present invention is illustrated by way of example and is not limited by the figures of the accompanying drawings, in which like references indicate similar elements, and in which:

FIG. 1 is a block diagram of the key components for ECC and DBI calculations in one embodiment.

FIG. 2 is one embodiment of the DBI generation circuitry that occurs within the DBI generation block.

FIG. 3 is a flow diagram of one embodiment of a process for performing error checking and correcting and data bus inversion in parallel.

### DETAILED DESCRIPTION OF THE INVENTION

Embodiments of an effective method to perform an approximate data bus inversion (DBI) calculation and the ECC generation and correction calculations in parallel to reduce, and potentially minimize the latency on a data communication bus are disclosed. In the following description, numerous specific details are set forth. However, it is understood that embodiments may be practiced without these specific details. In other instances, well-known elements, specifications, and protocols have not been discussed in detail in order to avoid obscuring the present invention.

Using both DBI and ECC on the signal lines of a bus is beneficial for data integrity and power consumption among other potential benefits. One problem with using both of these proven techniques together is that each one requires a certain time period to complete their calculations and subsequently allow the data to flow across the bus. If DBI were to be strictly implemented with ECC on the same bus the two techniques would operate in series (i.e. one calculation at a time). A series implementation would be required because one or more bits used for DBI calculations could be subsequently corrected by ECC and the DBI result potentially would not be entirely accurate. Thus, ECC calculations would be completed in one discrete step and then the DBI calculation would be completed in a subsequent step. In this situation the latency generated by both calculations done in series adds to the delay of the data arriving at its receiving destination.

Although, since the majority of ECC algorithms are able to correct only a small number of bits (e.g. single bit correction is the most common bit correction amount) an approximate DBI result calculated in parallel with ECC calculations would reduce, and potentially minimize, the latency associated with both sets of calculations. These parallel calculations would lead to an approximate DBI calculation result that could be incorrect at most by the number of bit signals corrected by ECC. Although, in the majority of circumstances where ECC corrects only one bit (or a small number of bits) this error factor introduced to the DBI calculation would be insignificant or in most cases non-existent. The error factor would only be potentially introduced in a circumstance where the difference between the number of logical one signal lines and the number of logical zero signal lines is less than the number of bits corrected by ECC. Thus, this approximate DBI implementation would accomplish generally the same goals as a strict DBI implementation with the added benefit of running in parallel with ECC calculations to minimize latency.

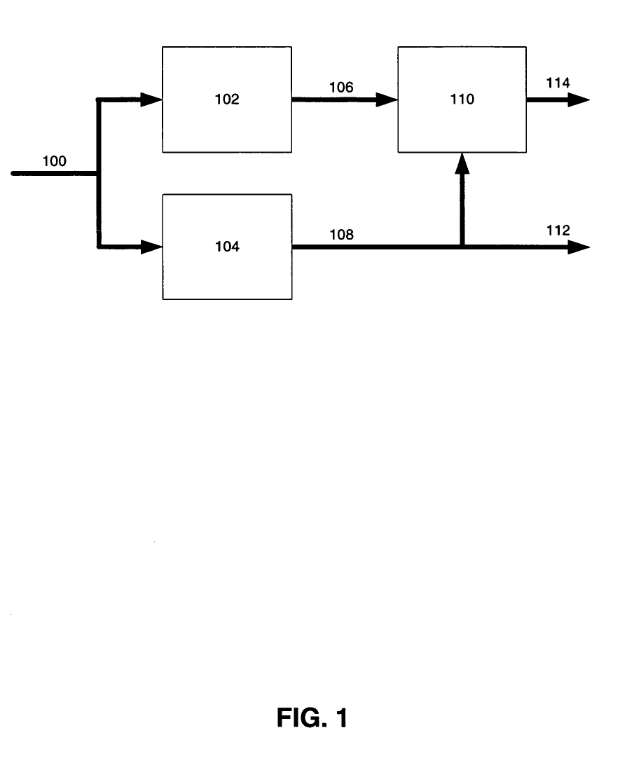

FIG. 1 is a block diagram of the key components for ECC and DBI calculations in one embodiment. A data value is sent across a data communication bus 100. In one embodiment, the data communication bus 100 is the front side bus in a computer system located between a processor and a memory controller hub (MCH). The MCH is commonly referred to as the northbridge in a chipset. In one embodiment, the MCH connects the processor to the system memory by way of the data communication bus 100. In different embodiments, the flow of the block diagram can be that of data flowing from the processor to the chipset, from the chipset to the processor, from the chipset to the system memory, from the system memory to the chipset, or any one of many other flows of data between components across a bus in a computer system. The data communication bus 100 is a number of individual bus signal lines, each of which can transmit one bit of data at a given time. In different embodiments, the data communication bus 100 and, thus, the data value sent across the bus may be any given number of bits such as 32 bits, 64 bits, or 128 bits. The data communication bus 100 may also run at many different frequencies in different embodiments of the invention. In different embodiments, the data communication bus runs at 66 MHz, 100 MHz, 133 MHz, 266 MHz, or one of many other bus frequencies.

In one embodiment, the data value is comprised of a number of data bits and it is coupled to an ECC value that is comprised of a number of ECC bits. The data value and coupled ECC value are sent across the data communication bus 100 to an ECC checking and correcting block 102 and to a DBI calculation block 104. In one embodiment, the data value and coupled ECC value arrive at both blocks at relatively the same time. The ECC checking and correcting block 102 receives the data value and coupled ECC value and subsequently determines whether the data value and coupled ECC value have any errors on the bus signal lines. Once the check is performed on the data bits and ECC bits, the check results are then used to correct any errors in the original bit values arriving on data communication bus 100. The resulting bit values, whether unchanged (if no error was found) or corrected (if an error was found) is sent on data communication bus 106 to the DBI generate block 110. In different embodiments, the ECC checking algorithm performed on the data in the ECC checking and correcting block 102 can be any one of a number of common ECC checking algorithms (E.g. Hamming code, Reed-Solomon code, Binary Golay code, etc.).

In one embodiment, the corrected results of the data value and coupled ECC value are equal to the original subset of data bit values and ECC bit values that had no errors coupled with the remaining subset of corrected data bit values and ECC bit values. These two subsets of bit values, when taken together, comprise a newly corrected value of data bits and ECC bits. If no errors were found during the ECC check, then the new data value and coupled ECC value is equal to the original data value and coupled ECC value. In one embodiment, the data value is 64 bits wide and the ECC value is 8 bits wide, thus, in this embodiment, the width of the total data input into the ECC checking and correcting block 102 is 72 bits wide. Thus, the total data output from the ECC checking and correcting block onto the data communication bus 106 and into the DBI generation block 110 is also 72 bits wide. In another embodiment, the data arriving at the ECC checking and correcting block 102 has not had any ECC calculations performed yet, thus the data value would arrive not coupled to any ECC bits. Although, in this embodiment, the ECC calculation would still take place to create the ECC bits and the data output from the ECC checking and correcting block 102 onto data communication bus 106 would have newly coupled ECC bits.

The other block the data value is sent to on data communication bus 100 is the DBI calculation block 104. The DBI calculation block 104 receives the data value and determines through a calculation whether the entire number of bus signal lines should be inverted. In one embodiment, the calculation determines the ratio of the number total bus signal lines (i.e. the bit width of the bus) to the number of bus signal lines that are currently in a logical one position (i.e. a bit value of one). The data on the entire bus will be inverted if the calculated ratio shows that there are more logical one bus signal lines than logical zero (i.e. a bit value of zero) bus signal lines. For example, if the bus is 64-bits wide and the data value located on the bus has 40 bit values at logical one and 24 bit values at logical zero, the data on the bus will be inverted. Thus, in this example, the inverted bus would have 24 bit values at logical one and 40 bit values at logical zero. The DBI calculation block 104 only determines if the inversion will take place, it does not invert the data. The DBI calculation results are sent on DBI bus 108 to DBI generate block 110.

In one embodiment, the data value arrives at the DBI calculation block 104 with coupled ECC bits from a prior ECC calculation. In one embodiment, the DBI calculation block 104 receives the data value and the coupled ECC value, but only performs calculations to determine bus inversion based on data value only, not the ECC value. Thus, if the data value is 64 bits wide and the ECC value is 8 bits wide, the DBI calculation will only operate on the 64 bits of data. In another embodiment, the DBI calculation block 104 receives the data value and the coupled ECC value and performs calculations to determine bus inversion based on both the data value and the coupled ECC value. Thus, if the data value is 64 bits wide and the ECC value is 8 bits wide, the DBI calculation will operate on all 72 bits of data.

The DBI generate block 110 receives information consisting of both the value from the ECC checking and correcting block 102 via data communication bus 106 and the DBI calculation results data via DBI bus 108. The DBI generate block 110 uses both of these pieces of data in order to function, thus, in one embodiment, the DBI generate block 110 stores whichever piece of information that arrives first and waits for the second piece of information. If the DBI calculation results notify the DBI generate block 110 to perform a data bus inversion, the DBI generate block 110 then inverts the data value that was received from the ECC checking and correcting block 102 via data communication bus 106. Thus, every bit value of the received value is inverted, including the ECC bits. Otherwise, if the DBI calculation results notify the DBI generate block 116 to not perform the data bus inversion, no inversion will take place and the received data from data communication bus 106 remains the same. The resulting data value, whether inverted or not, is place on data communication bus 114, which sends the data to its destination. The DBI results that are sent by the DBI calculation block 104 are also sent to the data destination via DBI bus 112 to notify the receiver of the data sent on data communication bus 114 whether or not the data is inverted.

The DBI calculation and generation can take place on any bit-width granularity. Thus, in different embodiments, if the data communication bus is 64 bits wide, the DBI calculation and generation can be made for every 8 bits of data on the bus, 16 bits, 32 bits, 64 bits, or any other logical subset of 64 bits. For example, in the 16-bit embodiment, the calculation to determine whether or not to invert is made separately for bits 0-15, bits 16-31, bits 32-47, and bits 48-63. Therefore, four separate inversion calculations would be completed and those calculations would render four separate DBI determination bits, each individual bit signifying whether to invert each sixteen bits of data. Thus, in this embodiment, the DBI calculation results sent out from the DBI calculation block 104 via DBI bus 108 would be a 4-bit value. In many embodiments, the DBI calculation results are represented by DINV bits 0-3 in a common data bus inversion configuration. In one embodiment where there is a 4-bit DINV value that is determined for a 64-bit data value and an 8-bit ECC value, DINV bit 0 would determine whether to invert data bits 0-15 as well as coupled ECC bits 0 and 1, DINV bit 1 would determine whether to invert data bits 16-31 as well as coupled ECC bits 2 and 3, and so on.

In many embodiments of the present invention the ECC checking and correcting as well as the DBI calculating will take place in parallel. Once the data arrives at the ECC checking and correcting block 102 and the DBI calculation block 104, these two blocks can operate in parallel. Thus, the parallel nature of these blocks allows a portion of the aggregate latency caused by both blocks' calculations to be reduced. The result is a faster throughput of data from the sender of the data via data communication bus 100 to the receiver of the data via data communication bus 114.

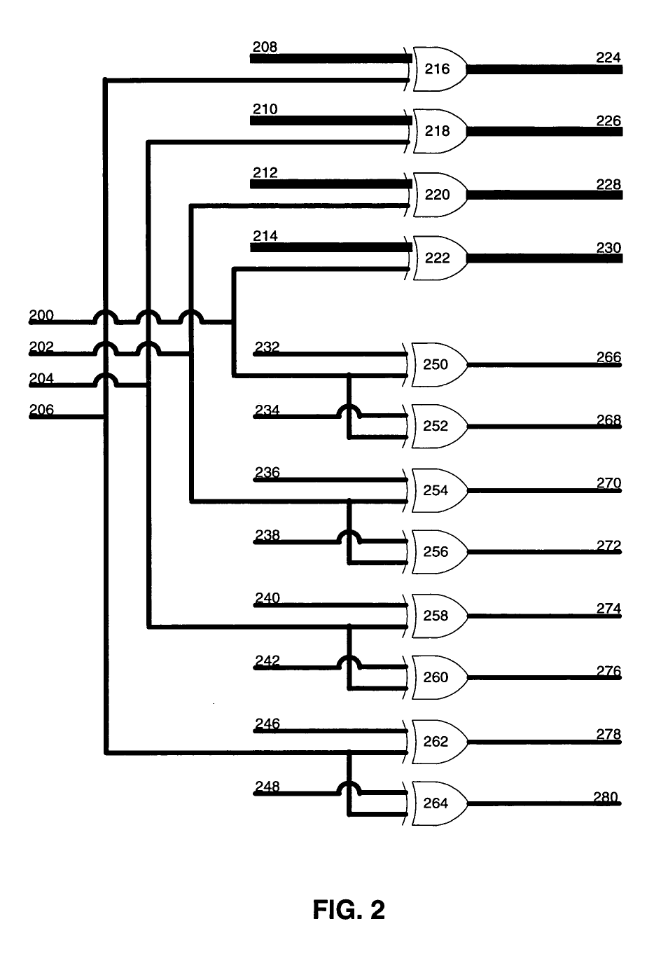

FIG. 2 is one embodiment of the DBI generation circuitry that occurs within the DBI generation block (110 in FIG. 1). In the embodiment shown, the ECC value coupled to the data is 8 bits wide, the data bus is 64 bits wide, and the DBI granularity is 16 bits of data and 2 bits of ECC per DINV bit. The DBI calculation results (i.e. the DINV bits) are represented by bus lines 200, 202, 204, and 206. Each DINV bit line is connected to 16 bits of the bus (208, 210, 212, and 214) through a set of exclusive or (XOR) gates (216, 218, 220, and 222). Each of the gates 216, 218, 220, and 222 are actually representative of 16 separate XOR gates. Thus, each bus signal line is separately connected to a DINV bit line through an XOR gate. For example, if DINV bit 0 (I.e. DINV bus line 200) is a logical one, then data bus bits 0-15 (represented by bus line 214) will be inverted by way of the 16 XOR gates (represented by XOR gate 222). Moreover, if DINV bit 2 (I.e. DINV bus line 202) is a logical zero, then data bus bits 32-47 (represented bus line 210) will not be inverted by way of the 16 XOR gates (represented by XOR gate 218). Regardless of whether or not each set of four 16-bit data bus values is inverted, the data bus XOR results are sent out on the data bus in 16-bit wide groups (represented by bus lines 224, 226, 228, and 230) which are then combined to form the resulting 64-bit wide data value that is sent onto the data communication bus.

Additionally, in this embodiment, the individual ECC bits are shown (bus signal lines 232-248). These ECC bus lines are connected in pairs to each DINV bus line through an XOR gate (gates 250-264) and the resulting values of inverted and non-inverted ECC values are sent onto the data communication bus through bus signal lines 266-280. For example, in this embodiment, DINV bit 0 (DINV bus signal line 200) is connected to ECC bits 0 and 1 (ECC bus signal lines 232 and 234) through XOR gates 250 and 252 respectively. Therefore, if DINV bit 0 is a logical one, ECC bits 0 and 1 will be inverted by XOR gates 250 and 252 respectively and the resulting inverted ECC bits 0 and 1 will be sent onto the data communication bus through bus signal lines 266 and 268. The resulting data that is output from the DBI generation block is a 72-bit value that includes 64 bits of data and 8 bits of ECC. Thus, in this embodiment, the 72-bit value is controlled by the DINV bits in the following way:
DINV Bit 0 modifies Data Bus Bits 0-15 and ECC Bits 0-1
DINV Bit 1 modifies Data Bus Bits 16-31 and ECC Bits 2-3
DINV Bit 2 modifies Data Bus Bits 3247 and ECC Bits 4-5
DINV Bit 3 modifies Data Bus Bits 48-63 and ECC Bits 6-7

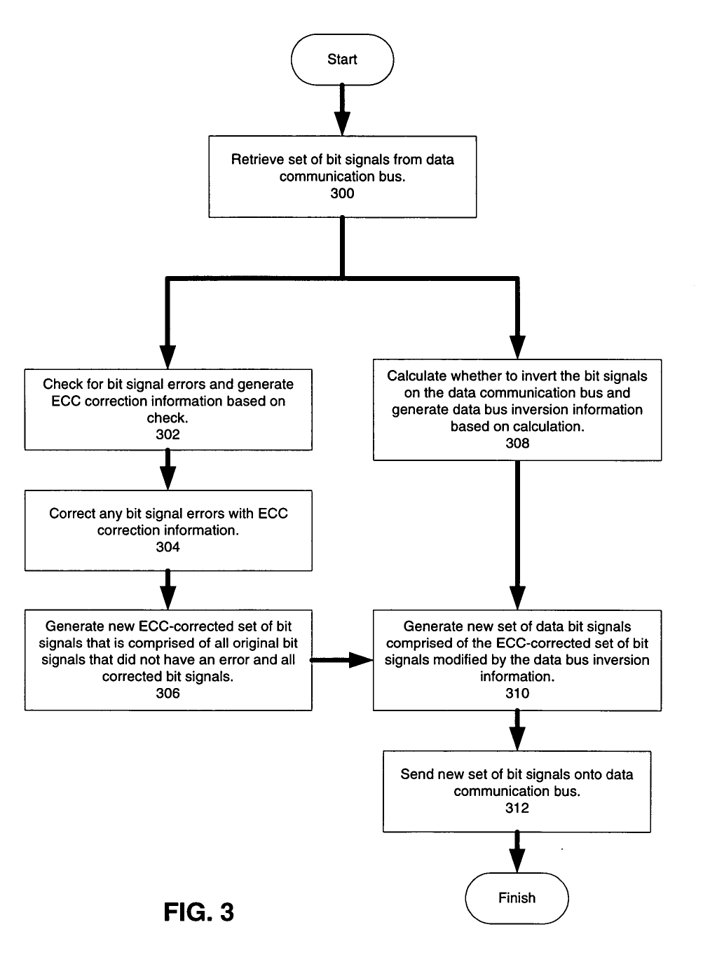

FIG. 3 is a flow diagram of one embodiment of a process for performing error checking and correcting and data bus inversion in parallel. The process is performed by processing logic that may comprise hardware (circuitry, dedicated logic, etc.), software (such as is run on a general purpose computer system or a dedicated machine), or a combination of both. Referring to FIG. 3, the processing logic begins the process by retrieving a set of bit signals from a data communication bus (processing block 300). The bit signals comprise a data value that is equal to the width of the data communication bus. In one embodiment, the bit signals are sent from a processor. In another embodiment, the bit signals are sent from a chipset northbridge device. In yet another embodiment, the bit signals are sent from a system memory module. In one embodiment, the bit signals can comprise exclusively a data value. In another embodiment, a subset of the bit signals are a data value and the rest are an ECC value.

Next, as the process continues, two things happen relatively simultaneously, the processing logic performs error checking and correcting calculations and the DBI calculations. In one embodiment, the ECC check process retrieves the bit signals that consist of the data value and an ECC value to perform the ECC check. In this embodiment, the processing logic checks the retrieved bit signals to determine if there are any errors and ECC correction information is generated if any errors exist (processing block 302). In one embodiment, this check is performed on all retrieved bit signals including the data value and the ECC value bit signals. Next, the processing logic corrects the bit signal errors (if any exist) using the ECC correction information (processing block 304). Then the processing logic generates a new set of ECC-corrected data that is comprised of all of the bit signals that did not have errors and the corrected bit signals that had errors (processing block 306). In another embodiment, the data value retrieved from the data communication bus does not have any coupled ECC value. Thus, in this embodiment, the processing logic does not check for errors during this iteration of the process. Instead, the processing logic generates the ECC bits and couples them to the data value for future ECC checks.

The other parallel path of the flow diagram begins with the processing logic retrieving the bit signals from the data communication bus for a DBI calculation (processing block 308) (as mentioned above). On this path of the flow diagram the processing logic then completes a calculation to determine whether or not to invert the bit signals on the data communication bus and DBI information is subsequently generated based on the results of the calculation (processing block 310). In one embodiment, the DBI calculation is performed on the bit signals that comprise the data value alone. In this embodiment, if ECC bits are coupled to the data bit signals, the calculation ignores the ECC bits. In another embodiment, the DBI calculation is performed on all bit signals including data value bit signals and the ECC value bit signals.

At this point the two separate flow diagram paths, which were operating on the bit signals in parallel, converge. Accordingly, the processing logic generates a new set of bit signals (processing block 312) comprised of the ECC-corrected bit signals (generated from processing block 306) modified by the DBI information (generated from processing block 308). Finally, the processing logic sends the new set of generated bit signals back onto the data communication bus (processing block 314) and the process is finished.

Thus, embodiments of an effective method to perform an approximate data bus inversion calculation and the ECC generation and correction calculations in parallel to minimize the latency on a data communication bus are disclosed. These embodiments have been described with reference to specific exemplary embodiments thereof. It will, however, be evident to persons having the benefit of this disclosure that various modifications and changes may be made to these embodiments without departing from the broader spirit and scope of the embodiments described herein. The specification and drawings are, accordingly, to be regarded in an illustrative rather than a restrictive sense.

1. A method, comprising:
determining whether to invert a first group of data bit signals; and
performing error checking and correction on the first group of data bit signals in parallel with the inversion determination.

2. The method of claim 1, further comprising:
creating a second group of data bit signals comprising a corrected version of the first group of data bit signals; and
inverting the second group of data bit signals if a determination was made to invert the first group of data bit signals.

3. The method of claim 2, further comprising receiving a first group of data bit signals on a data communication bus.

4. The method of claim 2, further comprising:
repairing any error in each individual data bit signal of the first group of data bit signals; and
creating the second group of data bit signals that comprises:
the set of data bit signals in the first group of data bit signals having no errors; and
the corrected set of data bit signals in the first group of data bit signals having errors.

5. The method of claim 4, wherein determining whether to invert the first group of data bit signals further comprises:
determining a total number of individual data bit signals in the first group;
determining a number of individual data bit signals in the first group that are at a logical one value;
electing to invert every data bit signal in the first group of data bit signals if the data bit signals in the first group being a logical one number are greater than half the total number of data bit signals in the first group; and
electing not to invert any data bit signal in the first group if the data bit signals in the first group being a logical one number are less than or equal to half the total number of data bit signals in the first group.

6. The method of claim 2, further comprising detaching any error checking code bit signals attached to the first group of data bit signals upon receipt before a determination is made whether to invert the first group of data bit signals.

7. An apparatus, comprising:
an error checking and correcting unit to check whether any errors exist in a first group of data bit signals and to correct any errors that exist; and
a bit signal inversion unit to determine whether to invert the first group of data bit signals, wherein the determination occurs in parallel with the checking and correcting of any errors in the first group of data bit signals.

8. The apparatus of claim 7, wherein the error checking and correcting unit is further adapted to:
repair any error in each individual data bit signal of the first group of data bit signals; and
create a second group of data bit signals comprising:
the set of data bit signals in the first group of data bit signals having no errors; and
the corrected set of data bit signals in the first group of data bit signals having errors.

9. The apparatus of claim 8, wherein the bit signal inversion unit is further adapted to:
determine a total number of data bit signals in the first group;
determine a number of data bit signals in the first group that are at a logical one value;
elect to invert every data bit signal in the first group if the data bit signals in the first group having a logical one number are greater than half of the total number of data bit signals in the first group; and
elect not to invert any data bit signal in the first group if the data bit signals in the first group being a logical one number are less than or equal to half of the total number of data bit signals in the first group.

10. The apparatus of claim 7, further adapted to exclude any error checking code bit signals that are attached to the first group of data bit signals upon receipt before a determination is made whether to invert the first group of data bit signals.

11. A method, comprising:
receiving a first group of data bit signals on a data communication bus;
determining whether to invert the first group of data bit signals;
performing error checking and correction on the first group of data bit signals, wherein the error checking and correction occurs in parallel with the inversion determination;
creating a second group of data bit signals that is comprised of the corrected first group of data bit signals; and
inverting the second group of data bit signals if the determination was made to invert the first group of data bit signals.

12. The method of claim 11, further comprising:
repairing any error in each individual data bit signal comprising the first group of data bit signals; and
creating the second group of data bit signals that is comprised of:
the set of data bit signals in the first group of data bit signals that did not have any errors; and
the corrected set of data bit signals in the first group of data bit signals that did have errors.

13. The method of claim 12, wherein determining whether to invert the first group of data bit signals further comprises:
determining the total number of individual data bit signals in the first group;
determining the number of individual data bit signals in the first group that are at a logical one value;
electing to invert every individual data bit signal in the first group if the count of logical one value data bit signals in the first group is greater than half of the count of the total number of data bit signals in the first group; and
electing not to invert any data bit signal in the first group if the count of logical one value data bit signals in the first group is less than or equal to half of the count of the total number of data bit signals in the first group.

14. A system, comprising:
a bus; and
a chipset connected to the bus, the chipset comprising:
an error checking and correcting unit that checks whether any errors exist in a first group of data bit signals and to correct any errors in the first group of data bit signals and places the results of the corrected first group of data bit signals in a second group of data bit signals; and
a bit signal inversion unit that determines whether to invert the first group of data bit signals, wherein the determination occurs in parallel with the checking and correcting of any errors in the first group of data bit signals, and that inverts the second group of data bit signals if the determination was made to invert the first group of data bit signals.

15. The system of claim 14, wherein the system:
repairs any error in each individual data bit signal comprising the first group of data bit signals; and
creates the second group of data bit signals that is comprised of:
the set of data bit signals in the first group of data bit signals that did not have any errors; and
the corrected set of data bit signals in the first group of data bit signals that did have errors.

16. The system of claim 15, wherein the system:
determines the total number of data bit signals in the first group;
determines the number of data bit signals in the first group that are at a logical one value;
elects to invert every data bit signal in the first group if the count of logical one value data bit signals in the first group is greater than half of the count of the total number of data bit signals in the first group; and
elects not to invert any data bit signal in the first group if the count of logical one value data bit signals in the first group is less than or equal to half of the count of the total number of data bit signals in the first group.
